(19) United States
(12) Patent Application Publication
(10) Pub. No.: US 2008/0054436 A1
(43) Pub. Date: Mar. 6, 2008

(54) Semiconductor Device and Fabricating Method Thereof

(76) Inventor: In Cheol Baek, Suwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/846,738

(22) Filed: Aug. 29, 2007

(30) Foreign Application Priority Data
Aug. 29, 2006 (KR) 10-2006-0082546

(51) Int. Cl. H01L 23/48; H01L 21/4763

(52) U.S. Cl. 257/686; 257/751; 257/762; 257/763; 257/774; 438/620; 257/E23.168; 257/E23.174; 257/E21.597

(57) ABSTRACT

A semiconductor device and a fabricating method thereof are provided. A PMD layer is formed on a semiconductor substrate, and at least one IMD layer is formed on the PMD layer. A through-electrode penetrates through the semiconductor substrate, the PMD layer, and each IMD layer, and a heat emission wiring is formed on an underside of the semiconductor substrate.

### CROSS-REFERENCE TO RELATED APPLICATION

The present application claims the benefit under 35 U.S.C. §119 of Korean Patent Application No. 10-2006-0082546, filed Aug. 29, 2006, which is hereby incorporated by reference in its entirety.

### BACKGROUND

Semiconductor devices are often arranged in a System In a Package (SiP) shape. FIG. 1 shows a cross-section of a related art SiP semiconductor device.

Referring to FIG. 1, the related art semiconductor device in a SiP shape has an interposer 1, a first device 3, a second device 5, and a third device 7.

The first device 3, second device 5, and third device 7 can each be, for example, any one of the following group: a Central Processing Unit (CPU), Static Random Access Memory (SDRAM), Dynamic Access Memory (DRAM), Flash Memory, Logic Large Scale Integration (LSI), a Power Integrated Circuit (IC), a Control IC, Analog LSI, a Mixed Mode Integrated Circuit (MM IC), a Complimentary Metal Oxide Semiconductor Radio Frequency Integrated Circuit (CMOS RF-IC), a Sensor Chip, or a Micro Electro Mechanical Sensor (MEMS) Chip.

Between the first device 3 and the second device 5, and between the second device 5 and the third device 7, a connecting means is typically present for connecting signals between the respective devices.

When implementing commercialization of a semiconductor device in a SiP shape, the problem of heat radiation should first be solved. In particular, heat emission of a device formed in an interlayer such as the second device 15 is a common problem in the commercialization of SiP semiconductor devices.

Thus, there exists a need in the art for a SiP semiconductor device and fabricating method thereof that deals with the problem of heat emission.

### BRIEF SUMMARY

Embodiments of the present invention provide a semiconductor device and a fabricating method thereof capable of emitting heat from a device in a SiP shape.

In an embodiment, a PMD layer can be formed on a semiconductor substrate, and at least one IMD layer can be formed on the PMD layer. A through-electrode penetrates through the PMD layer and the IMD layer, and a heat emission wiring is formed under the semiconductor substrate on a lower surface thereof.

In an embodiment, a semiconductor device comprises: an interposer; a plurality of devices stacked and formed on the interposer; at least one through-electrode formed within the plurality of devices, penetrating through the devices; a heat emission wiring formed on a lower surface of each device forming the plurality of devices; and a heat sink connected to the heat emission wirings.

In an embodiment, a through-electrode penetrating through a plurality of devices can be formed. Each device in the plurality of devices has a heat emission wiring formed under a semiconductor substrate. The plurality of devices can be stacked on an interposer, and a heat sink can be formed connected to the heat emission wirings.

### BRIEF DESCRIPTION OF THE DRAWINGS

FIG. 1 is a cross-sectional view of a related art semiconductor device in a System In a Package scheme.

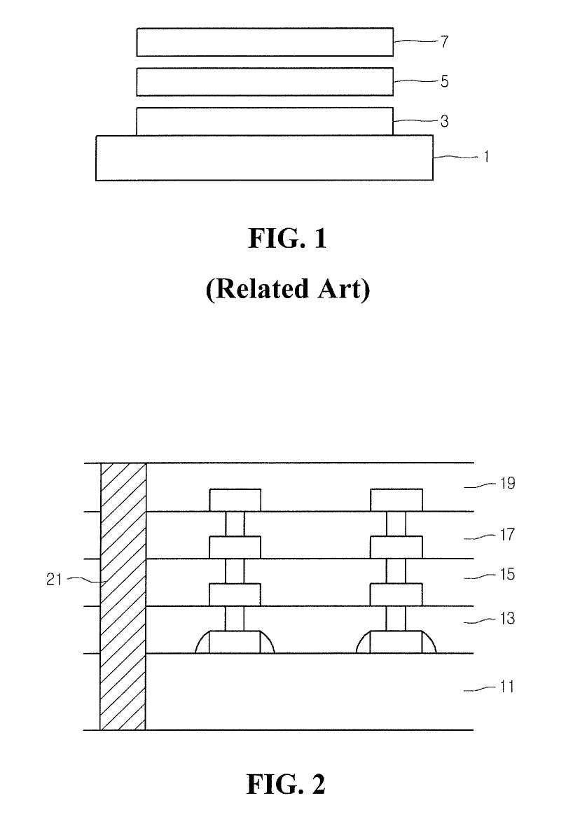

FIGS. 2 to 4 are cross-sectional views showing a fabricating method of a semiconductor device according to an embodiment of the present invention.

FIG. 5 is a cross-sectional view showing a semiconductor device stacked in a SiP shape according to an embodiment of the present invention.

### DETAILED DESCRIPTION

When the terms “on” or “over” are used herein, when referring to layers, regions, patterns, or structures, it is understood that the layer, region, pattern or structure can be directly on another layer or stricture, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

Embodiments of the present invention will now be described in detail with reference to the accompanying drawings.

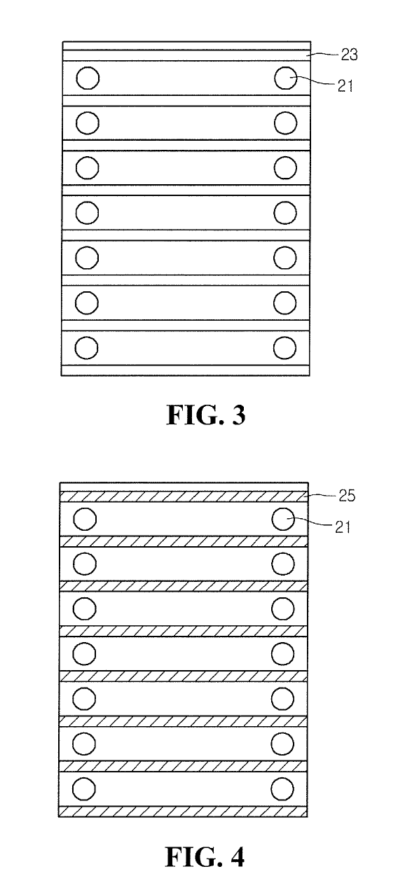

Referring to FIG. 2, in an embodiment, a pre-metal dielectric (PMD) layer 13 can be formed on a semiconductor substrate 11, and at least one inter-metal dielectric (IMD) layer can be formed on the PMD layer 13. For example, a first IMD layer 15, a second IMD layer 17, and a third IMD layer 19 can each be formed on the PMD layer 13.

A through-electrode 21 penetrating the device can be formed. The through-electrode 21 can be formed by penetrating the PMD layer 13, and each IMD layer (for example, 15, 17, and 19). Also, the through-electrode 21 can be formed by penetrating the semiconductor substrate 11 as needed.

The semiconductor substrate 11 on which the PMD layer 13 is formed can include a transistor area.

The transistor area can be formed on the semiconductor substrate 11. Also, a contact can be formed on the PMD layer 13. Methods of fabricating the PMD layer 13 are well known in the art.

The through-electrode 21 can be formed to penetrate through the third, second, and first IMD layers 19, 17, and 15 and the PMD layer 13. In an embodiment, the through-electrode 21 can be formed up to the boundary surface where the semiconductor substrate 11 is exposed.

The through-electrode 21 can be formed by sequentially performing a pattern process, an etching process, a metal formation process, and a chemical mechanical polishing (CMP) process for each IMD layer (for example, 15, 17, and 19) and the PMD layer 13. The through-electrode 21 can be formed of, for example, tungsten (W), copper (Cu), aluminum (Al), silver (Ag), gold (Au), or some combination thereof. The through-electrode 21 can be deposited by chemical vapor deposition (CVD), physical vapor deposition (PVD), Evaporation, electrochemical plating (ECP), or any other appropriate method known in the art. Also, the through-electrode 21 can have a barrier metal formed of TaN, Ta, TiN, Ti, TiSiN, or any other appropriate material known in the art. The barrier metal can be formed by CVD, PVD, atomic layer deposition (ALD), or any other appropriate method known in the art.

In an embodiment, the through-electrode 21 can be formed to penetrate through the semiconductor substrate 11 by collectively penetrating through the semiconductor substrate 11. In a further embodiment, the through-electrode 21 can be formed by separately performing an etching process on the semiconductor substrate 11.

Referring to FIG. 3, a trench 23 can be formed on the lower surface of the semiconductor substrate 11. The trench 23 can be formed between through-electrodes 21. In an embodiment, the trench 23 can be formed on the lower surface of the semiconductor substrate 11 through a photo process and an etching process.

Referring to FIG. 4, a heat emission wiring 25 can be formed on the trench 23. The heat emission wiring can be formed of, for example, W, Cu, Al, Ag, Au, or any combination thereof. In an embodiment, when forming the heat emission wiring 25 in the trench 23, a SiN film can also be formed on the trench 23. The SiN film can inhibit the generation of leakage current. The heat emission wiring 25 can be formed by a deposition process and CMP. For example, the deposition process can be CVD, PVD, ALD, or any other appropriate deposition method known in the art.

Referring again to FIGS. 2-4, a semiconductor device according to an embodiment of the present invention can include a semiconductor substrate 11 having a trench 23 provided at its underside. A PMD layer 13 can be formed on the semiconductor substrate 11, and at least one IMD layer (for example, 15, 17, and 19) can be formed on the PMD layer 13. Also, a through-electrode 21 can penetrate each IMD layer and the PMD layer 13, and a heat emission wiring 25 can be formed on the trench 23.

Accordingly, when using the semiconductor device and fabricating method thereof in a SiP shape, heat can easily be emitted from stacked devices in the SiP by using the heat emission wiring.

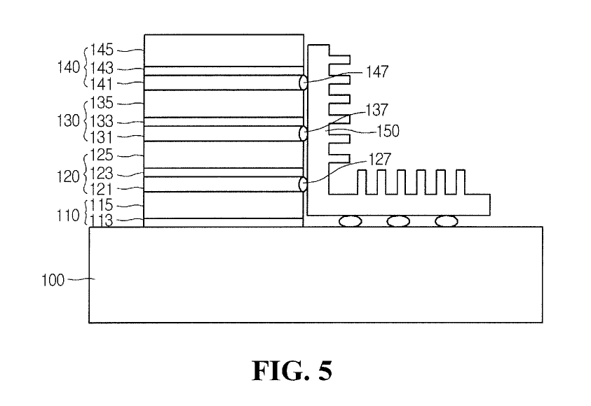

Referring to FIG. 5, a semiconductor device stacked in a SiP shape according to an embodiment of the present invention can include an interposer 100 and a plurality of devices stacked on the interposer 100. Each device in the plurality of devices can independently be, for example, any one of the following devices: a CPU, SRAM, DRAM, Flash Memory, Logic LSI, a Power IC, a Control IC, Analog LSI, an MM IC, a CMOS RF-IC, a Sensor Chip, or a MEMS Chip.

Any number of devices can be stacked on the interposer 100. For example, four devices could be stacked on the interposer 100. Referring again to FIG. 5, a first device 110, a second device 120, a third device 130, and a fourth device 140 can be stacked on the interposer 100.

The first device 110 can comprise a first semiconductor substrate 113 and a first insulating film 115 on the semiconductor substrate 113. The first insulating film 115 can include a PMD layer, an IMD layer, or both. Also, a first heat emission wiring (not shown) can be formed on the lower surface of the first semiconductor substrate 113.

The second device 120 can include a second semiconductor substrate 123 and a second insulating film 125 on the second semiconductor substrate 123. The second insulating film 125 can comprise a PMD layer, an IMD layer, or both. Also, a second heat emission wiring 123 can be formed on the lower surface of the second semiconductor substrate 123.

The third device 130 can comprise a third semiconductor substrate 133 and a third insulating film 135 on the third semiconductor substrate 133. The third insulating film 135 can include a PMD layer, an IMD layer, or both. Also, a third heat emission wiring 131 can be formed on the lower surface of the second semiconductor substrate 133.

The fourth device 140 can comprise a fourth semiconductor substrate 143 and a fourth insulating film 145 on the fourth semiconductor substrate 143. The fourth insulating film 145 can include a PMD layer, an IMD layer, or both. Also, a fourth heat emission wiring 141 can be formed on the lower surface of the fourth semiconductor substrate 143.

Each device in the SiP (for example, 110, 120, 130, and 140) is provided with at least one through-electrode penetrating through the device. Accordingly, the devices (for example, 110, 120, 130, and 140) can be connected to signals by using the through-electrodes.

In an embodiment, a semiconductor device has a heat sink 150 on the interposer 100. The heat sink can be connected to the second, third, and fourth devices 120, 130, and 140 through a second, third, and fourth radiating terminal 127, 137, and 147. The second radiating terminal 127 can be connected to the second heat emission wiring 121, the third radiating terminal 137 can be connected to the third heat emission wiring 131, and the fourth radiating terminal 147 can be connected to the fourth heat emission wiring 141. Accordingly, the semiconductor device stacked in a SiP shape can efficiently emit heat from the stacked devices.

A fabricating method of a semiconductor device stacked in a SiP shape according to an embodiment of the present invention can include forming a through-electrode penetrating through the device. A plurality of devices can be formed, each with heat emission wirings formed under a semiconductor substrate of the device. Then, the plurality of devices can be stacked on an interposer, and a heat sink can be formed. The heat sink can be connected to the heat emission wiring in each device.

Each heat emission wiring can be formed on a trench provided on the lower surface of the semiconductor substrate of each device. In an embodiment, the forming of each heat emission wiring can further comprise forming a SiN film between the trench and the heat emission wiring. A radiating terminal connecting the heat emission wiring to the heat sink can be formed in each device.

The semiconductor device and the fabricating method thereof each have the advantage of being able to easily emit heat devices in a SiP shape.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a semiconductor substrate;
a PMD layer on the semiconductor substrate;
at least one IMD layer on the PMD layer;
a through-electrode penetrating through the semiconductor substrate, the PMD layer, and the at least one IMD layer; and
a heat emission wiring on a lower surface of the semiconductor substrate.

2. The semiconductor device according to claim 1, wherein the through-electrode is comprises at least one material selected from the group consisting of W, Cu, Al, Ag, and Au.

3. The semiconductor device according to claim 1, wherein the heat emission wiring comprises at least one material selected from the group consisting of W, Cu, Al, Ag, and Au.

4. The semiconductor device according to claim 1, further comprising a SiN film between the lower surface of the semiconductor substrate and the heat emission wiring.

5. The semiconductor device according to claim 1, wherein the through-electrode comprises a barrier metal, and wherein the barrier metal comprises a material selected from the group consisting of TaN, Ta, TiN, Ti, and TiSiN.

6. A method of fabricating a semiconductor device, comprising:
forming a PMD layer on a semiconductor substrate;
forming at least one IMD layer on the PMD layer;
forming a through-electrode penetrating through the at least one IMD layer, the PMD layer, and the semiconductor substrate;
forming a trench on a lower surface of the semiconductor substrate; and
forming a heat emission wiring on the trench.

7. The method according to claim 6, wherein the through-electrode comprises at least one material selected from the group consisting of W, Cu, Al, Ag, and Au.

8. The method according to claim 6, wherein the heat emission wiring comprises at least one material selected from the group consisting of W, Cu, Al, Ag, and Au.

9. The method according to claim 6, further comprising forming a SiN film in the trench.

10. The method according to claim 6, wherein the through-electrode comprises a barrier metal, and wherein the barrier metal comprises a material selected from the group consisting of TaN, Ta, TiN, Ti, and TiSiN.

11. The method according to claim 6, wherein the forming the heat emission wiring comprises performing a deposition process and chemical mechanical polishing.

12. A package, comprising:
an interposer;
a plurality of devices stacked on the interposer;
at least one through-electrode penetrating through the plurality of devices;
a heat emission wiring under at least one device of the plurality of devices; and
a heat sink connected to the heat emission wiring.

13. The package according to claim 12, wherein the heat emission wiring is formed in a trench on a lower surface of a semiconductor substrate of the at least one device of the plurality of devices.

14. The package according to claim 12, further comprising a SiN film under at least one device of the plurality of devices.

15. The package according to claim 12, further comprising a radiating terminal connecting the heat emission wiring to the heat sink.

16. The package according to claim 12, wherein each device in the plurality of devices is independently selected from the group consisting of a CPU, SRAM, DRAM, Flash Memory, Logic LSI, a Power IC, a Control IC, Analog LSI, an MM IC, a CMOS RF-IC, a Sensor Chip and an MEMS Chip.

17. The package according to claim 12, wherein the at least one through-electrode comprises a barrier metal, and wherein the barrier metal comprises a material selected from the group consisting of TaN, Ta, TiN, Ti, and TiSiN.

18. The package according to claim 12, wherein the heat emission wiring under at least one device of the plurality of devices comprises a heat emission wiring under each device of the plurality of devices that is not directly on the interposer.

19. The package according to claim 18, wherein each heat emission wiring is connected to the heat sink.

20. The package according to claim 19, further comprising a radiating terminal connecting each heat emission wiring to the heat sink.
